(19) United States
(12) Patent Application Publication
(10) Pub. No.: US 2014/0007937 A1
(43) Pub. Date: Jan. 9, 2014

(54) ELECTROCONDUCTIVE PASTE AND SOLAR CELL

(71) Applicant: MURATA MANUFACTURING CO., LTD., Nagaokakyo-Shi (JP)

(72) Inventor: Yorinobu Maeda, Nagaokakyo-Shi (JP)

(73) Assignee: MURATA MANUFACTURING CO., LTD., Nagaokakyo-Shi (JP)

(21) Appl. No.: 13/963,303

(22) Filed: Aug. 9, 2013

Related U.S. Application Data
(63) Continuation of application No. PCT/JP2012/052708, filed on Feb. 7, 2012.

(30) Foreign Application Priority Data
Feb. 16, 2011 (JP) 2011-030703
Jul. 29, 2011 (JP) 2011-166344

(51) Int. Cl. H01L 31/0224

(52) U.S. Cl. CPC H01L 31/022425
USPC 136/256; 252/514

(57) ABSTRACT

An electroconductive paste contains an electroconductive powder, a non-lead-type glass frit, a binder resin, and a solvent, wherein the solvent contains at least one first solvent such as texanol that contains at least one of a carboxylate group and a hydroxyl group and at least one second solvent such as propylene carbonate that does not contain the carboxylate and the hydroxyl group and has a hydrogen-bond term among the Hansen solubility parameters of 7 (J/cm³)^{1/2} or less. A light-receiving surface electrode 3 is formed by using this electroconductive paste. By this, an electroconductive paste for forming an electrode of a solar cell having a good printing property and having good cell characteristics, and a solar cell manufactured by using this electroconductive paste are realized.

### CROSS REFERENCE TO RELATED APPLICATIONS

The present application is a continuation of International application No. PCT/JP2012/052708, filed Feb. 7, 2012, which claims priority to Japanese Patent Application No. 2011-030703, filed Feb. 16, 2011, and Japanese Patent Application No. 2011-166344, filed Jul. 29, 2011, the entire contents of each of which are incorporated herein by reference.

### FIELD OF THE INVENTION

The present invention relates to an electroconductive paste and a solar cell, and more particularly to an electroconductive paste suitable for forming an electrode of a solar cell as well as a solar cell manufactured by using this electroconductive paste.

### BACKGROUND OF THE INVENTION

A solar cell typically has a light-receiving surface electrode of a predetermined pattern formed on one principal surface of a semiconductor substrate. Also, a reflection-preventive film is formed on the semiconductor substrate excluding the light-receiving surface electrode, and the reflection loss of incident solar light is suppressed by the reflection-preventive film, whereby the conversion efficiency of solar light into electric energy is improved.

The light-receiving surface electrode is formed typically in the following manner using an electroconductive paste. That is, the electroconductive paste contains an electroconductive powder, a glass frit, and an organic vehicle containing at least a binder resin and a solvent. Further, the electroconductive paste is applied onto the surface of a reflection-preventive film formed on a semiconductor substrate, so as to form an electroconductive film having a predetermined pattern. Subsequently, in a firing step, the glass frit is fused, and the reflection-preventive film located under the electroconductive film is decomposed and removed, whereby the electroconductive film is sintered to form a light-receiving surface electrode, and the light-receiving surface electrode and the semiconductor substrate are bonded and electrically conducted with each other.

A method of decomposing and removing the reflection-preventive film in a firing step to bond the semiconductor substrate and the light-receiving surface electrode with each other in this manner is referred to as a fire-through (fire-through), and the conversion efficiency of a solar cell is largely dependent on the fire-through property. In other words, it is known in the art that, when the fire-through property is insufficient, the conversion efficiency decreases, thereby causing an inferior basic performance as a solar cell. For this reason, a technique of improving the fire-through property is eagerly being studied and developed from the past.

For example, Patent Document 1 proposes a glass composition for forming an electrode containing Bi₂O₃: 73.1% to 90%, B₂O₃: 2% to 14.5%, ZnO: 0% to 25%, MgO+CaO+SrO+BaO: 0.2% to 20%, SiO₂+Al₂O₃: 0% to 8.5% in a mass % representation converted in terms of oxide as a glass composition.

In this Patent Document 1, the electroconductive paste for forming an electrode contains a metal powder such as Ag, a glass powder made of the above-described glass composition for forming an electrode, and an organic vehicle made of a binder resin such as an ethyl cellulose resin and an arbitrary organic solvent such as α-terpineol or propylene carbonate. By allowing the glass component to be within the above-described composition range, a glass composition for forming an electrode having a good fire-through property and being excellent also in thermal stability is obtained.

Also, Patent Document 2 proposes a thick-film electroconductor in which at least one electroconductive powder and at least one glass frit are dispersed in an organic solvent, and the organic solvent contains one or more selected from the group of bis(2-(2-butoxyethoxy)ethyl) adipate, dibasic acid ester, octyl epoxy tallate, isotetradecanol, and hydrogenated rosin pentaerythritol.

In Examples of Patent Document 2, it is disclosed that, by allowing a dibasic acid ester to be contained in the electroconductive paste as the organic solvent in addition to texanol, the fill factor FF (Fill Factor), which is an index of the characteristics of the solar cell, is improved as compared with a case in which only texanol is used, whereby the conversion efficiency can be improved.
Patent Document 1: JP 2010-83748 A (claim 1, paragraphs [0044], [0053], and the like)
Patent Document 2: WO 2009/146398 (claim 1, and Tables 9 and 10)

### SUMMARY OF THE INVENTION

As described above, an electroconductive paste for forming an electrode of a solar cell typically contains an electroconductive powder, a glass frit (glass powder), and an organic vehicle containing at least a binder resin and a solvent. Further, since it is necessary that the solvent dissolves the binder resin, an organic material having a polar group such as a carboxylate group or a hydroxyl group is typically used in consideration of the solubility of the binder resin.

In other words, in Patent Document 1, though usability of an organic solvent having a non-polar group such as propylene carbonate is suggested, it is difficult to form a paste because organic solvents having a non-polar group are inferior in the solubility to a binder resin. For this reason, it is difficult to prepare a desired electroconductive paste. Therefore, in Patent Document 1, it is inevitable that an organic material having a polar group must actually be used, and an example using α-terpineol is described.

Also, in Patent Document 2, a particular organic solvent containing a hydroxyl group which is a polar group is used to form a paste. In other words, in Patent Document 2, an example is described in which a particular organic solvent such as a dibasic acid ester and an organic solvent having two or more polar groups such as texanol are mixed with each other so as to form a paste.

However, when only organic solvents having a polar group are used as in Patent Document 1 or in Patent Document 2, there have been raised the following problems.

In the case in which an organic solvent having a polar group is used, when the inorganic component (electroconductive powder, glass frit, or the like) in the electroconductive paste is wetted with the organic solvent, the inorganic component adheres onto an emulsion mask (hereafter simply referred to as “mask”) or a mesh of the pattern and adheres onto the semiconductor substrate via the reflection-preventive film of the thin film by a Coulomb force or a hydrogen bond generated via the organic solvent. When the inorganic component adheres onto the mask or the semiconductor substrate in this manner, the fluidity of the inorganic component to the pattern or the semiconductor substrate decreases. As a result of this, the electroconductive paste closely adheres onto the mask to generate plate clogging, thereby raising a fear of inviting deterioration of the plate releasing property. Further, since the fluidity of the inorganic component to the semiconductor substrate decreases, there is a fear that the packing property (packing property) of the inorganic component along the fine irregularity structure on the surface of the semiconductor substrate may decrease.

In other words, when only organic solvents having a polar group are used as in Patent Document 1 or in Patent Document 2, plate clogging is liable to occur, and deterioration of the plate releasing property is liable to be generated. For this reason, when continuous printing is carried out at a high speed, there is a fear that disconnection or the like may be generated in the light-receiving surface electrode or variations may be generated in the thickness of the light-receiving surface electrode. Also, since it is inferior in the packing property of the inorganic component as described above, the fire-through property also decreases and, for this reason, efficient and stable mass production of solar cells having desired good cell characteristics is difficult.

The present invention has been made in view of such circumstances, and an object thereof is to provide an electroconductive paste for forming an electrode of a solar cell having a good printing property and having good cell characteristics as well as a solar cell produced by using this electroconductive paste.

The present inventor has mixed a solvent having a carboxylate group or a hydroxyl group, which are polar groups, (hereafter also referred to as “polar solvent”) and a solvent without having these polar groups (hereafter also referred to as “non-polar solvent”) with each other and decreased the polarity of the mixed solvent to such a degree that the binder resin does not undergo poor dissolution. As a result of this, the present inventor has obtained a finding that, by using a mixed solvent in which a non-polar solvent having a hydrogen-bond term among the Hansen solubility parameters of 7 (J/cm³)^{1/2} or less is mixed with a polar solvent, occurrence of plate clogging can be suppressed, whereby the plate releasing property is improved, leading to an improvement in the printing property. Moreover, the present inventor has also obtained a finding that the fluidity of the inorganic component to the semiconductor substrate is improved, whereby the packing property is improved and the cell characteristics of the solar cell are also improved.

The present invention has been made based on such findings, and the electroconductive paste according to the present invention is an electroconductive paste for forming an electrode of a solar cell by printing, containing an electroconductive powder, a glass frit, a binder resin, and a solvent, wherein the solvent contains a first solvent that contains at least one of a carboxylate group and a hydroxyl group and a second solvent that does not contain the carboxylate and the hydroxyl group and has a hydrogen-bond term among the Hansen solubility parameters of 7 (J/cm³)^{1/2} or less.

In the electroconductive paste, the close adhesion property to the mask or mesh of the pattern decreases to a suitable extent at the time of printing, so that the fluidity to the pattern is enhanced without deteriorating the dissolution property to the binder resin. Also the amount of ejection to the pattern increases, and the plate clogging is less liable to occur, thereby improving the plate releasing property. As a result of this, even when continuous printing is carried out, disconnection of an electroconductive film can be suppressed, and variations in film thickness are suppressed, whereby the printing property is improved. Also, since the fluidity of the inorganic component to the semiconductor substrate is enhanced, the packing property of the inorganic component to the semiconductor substrate surface is improved. As a result of this, the fire-through property is improved, and the conversion efficiency can be improved.

Further, with respect to the electroconductive paste of the present invention, it is preferable that the second solvent contains at least one selected from diethylene glycol butyl methyl ether (hereafter referred to as “DEGBME”), triethylene glycol butyl methyl ether (hereafter referred to as “TEGBME”), diethylene glycol diethyl ether (hereafter referred to as “DEGDEE”), propylene carbonate, and n-tetradecane.

Also, as a result of further eager studies made by the present inventor, it has been found out that, by using a solvent in which the molar ratio of the oxygen moiety to the carbon moiety within a molecular structure is 0.3 or more as the second solvent, a further improvement of the fire-through property can be achieved without deteriorating the printing property. In this case, as the second solvent, solvents excluding n-tetradecane among the second solvents mentioned above are suitable.

In other words, with respect to the electroconductive paste of the present invention, it is preferable that the second solvent has at least an oxygen moiety and a carbon moiety within a molecular structure, and a molar ratio of the oxygen moiety to the carbon moiety is 0.3 or more.

By this, a further improvement of the fire-through property can be achieved without deteriorating the printing property.

Further, with respect to the electroconductive paste of the present invention, it is preferable that the second solvent contains at least one selected from DEGBME, TEGBME, DEGDEE, and propylene carbonate.

Because these have at least an oxygen moiety and a carbon moiety within a molecular structure and a molar ratio of the oxygen moiety to the carbon moiety is 0.3 or more, the aforesaid functions and effects can be easily exhibited.

Further, with respect to the electroconductive paste of the present invention, it is preferable that the first solvent contains at least one selected from texanol, dimethyl adipate, butylcarbitol acetate (hereafter referred to as “BCA”), and butylcarbitol (hereafter referred to as “BC”).

The present invention is particularly effective in the case of an electroconductive powder having hydrophilicity.

In other words, with respect to the electroconductive paste of the present invention, it is preferable that the electroconductive powder is surface-treated so as to be hydrophilic.

By this, the printing property and the fire-through property can be improved more effectively.

Further, with respect to the electroconductive paste of the present invention, it is preferable that the electroconductive powder is an Ag powder.

Further, with respect to the electroconductive paste of the present invention, it is preferable that the glass frit does not contain lead.

Further, the solar cell of the present invention is a solar cell in which a reflection-preventive film and an electrode that penetrates through the reflection-preventive film are formed on one principal surface of a semiconductor substrate, and the electrode is formed by sintering the electroconductive paste.

This allows the electroconductive paste to have a good printing property and a good fire-through property, and stable mass production of solar cells having a desired film thickness can be made without generating disconnection or the like even when continuous printing is carried out, whereby solar cells having a good conversion efficiency and excellent cell characteristics can be obtained with a good efficiency.

The electroconductive paste according to the present invention contains an electroconductive powder such as an Ag powder, a non-lead-type glass frit preferably not containing lead, a binder resin, and a solvent, wherein the solvent contains at least one first solvent (for example, texanol, dimethyl adipate, BCA, or BC) that contains at least one of a carboxylate group and a hydroxyl group and at least one second solvent (for example, DEGBME, TEGBME, DEGDEE, propylene carbonate, or n-tetradecane) that does not contain the carboxylate group and the hydroxyl group and has a hydrogen-bond term among the Hansen solubility parameters of 7 (J/cm³)^{1/2} or less. Therefore, in the electroconductive paste, the close adhesion property to the mask or mesh of the pattern decreases to a suitable extent at the time of printing. Further, the fluidity to the pattern is enhanced without deteriorating the dissolution property to the binder resin, so that the amount of ejection to the pattern increases, and the plate clogging is less liable to occur, thereby improving the plate releasing property. As a result of this, even when continuous printing is carried out, disconnection of an electroconductive film can be suppressed, and variations in film thickness are suppressed, whereby the printing property is improved. Also, since the fluidity of the inorganic component to the semiconductor substrate is enhanced, the packing property of the inorganic component to the semiconductor substrate surface is improved. As a result of this, the fire-through property is improved, and the conversion efficiency can be improved.

Also, according to the solar cell of the present invention, a reflection-preventive film and an electrode that penetrates through the reflection-preventive film are formed on one principal surface of a semiconductor substrate, and the electrode is formed by sintering the electroconductive paste according to any one of the above. This allows the electroconductive paste to have a good printing property and a good fire-through property, and stable mass production of solar cells having a desired film thickness can be made without generating disconnection or the like even when continuous printing is carried out, whereby solar cells having a good conversion efficiency and excellent cell characteristics can be obtained with a good efficiency.

### BRIEF EXPLANATION OF THE DRAWINGS

FIG. 1 is a cross-sectional view of a main part illustrating one embodiment of a solar cell manufactured by using an electroconductive paste according to the present invention.

FIG. 2 is an enlarged plan view schematically illustrating a light-receiving surface electrode side.

FIG. 3 is an enlarged bottom view schematically illustrating a back surface electrode side.

### DETAILED DESCRIPTION OF THE INVENTION

Next, embodiments of the present invention will be described in detail.

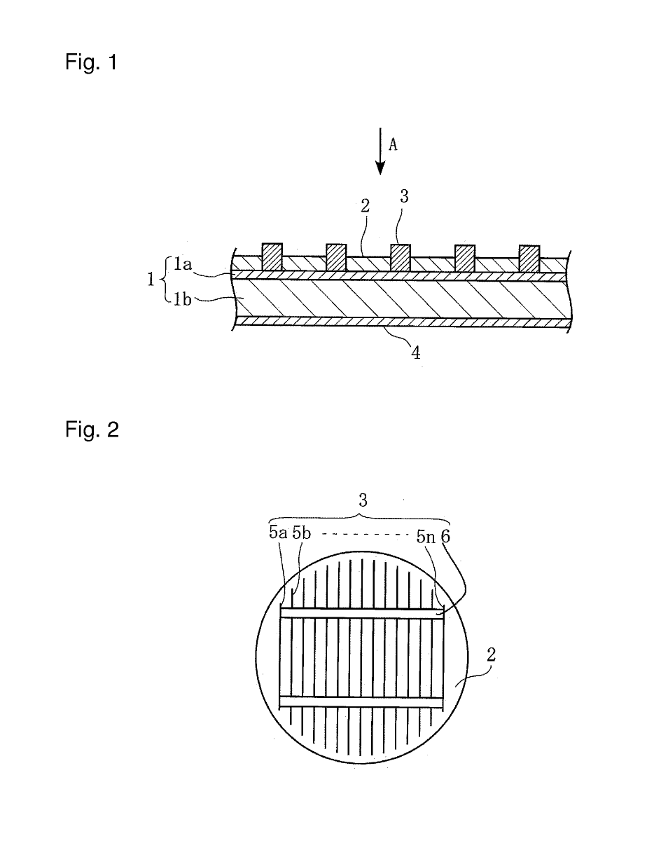

FIG. 1 is a cross-sectional view of a main part illustrating one embodiment of a solar cell manufactured by using an electroconductive paste according to the present invention.

In this solar cell, a reflection-preventive film 2 and a light-receiving surface electrode 3 are formed on one principal surface of a semiconductor substrate 1 containing Si as a major component, and a back surface electrode 4 is formed on the other principal surface of the semiconductor substrate 1.

The semiconductor substrate 1 has a p-type semiconductor layer 1b and an n-type semiconductor layer 1a, wherein the n-type semiconductor layer 1a is formed on the upper surface of the p-type semiconductor layer 1b. The semiconductor substrate 1 can be obtained, for example, by diffusing an impurity into one principal surface of a single-crystal or polycrystal p-type semiconductor layer 1b to form a thin n-type semiconductor layer 1a; however, the structure and the method of production thereof are not particularly limited as long as the n-type semiconductor layer 1a is formed on the upper surface of the p-type semiconductor layer 1b. Also, as the semiconductor substrate 1, a semiconductor substrate having a structure such that the thin p-type semiconductor layer 1b is formed on one principal surface of the n-type semiconductor layer 1a or a semiconductor substrate having a structure such that both of the p-type semiconductor layer 1b and the n-type semiconductor layer 1a are formed on a part of one principal surface of the semiconductor substrate 1 may be used. In any case, the electroconductive paste according to the present invention can be effectively used on a surface as long as the surface is the principal surface of the semiconductor substrate 1 on which the reflection-preventive film 2 is formed.

Here, in FIG. 1, the surface of the semiconductor substrate 1 is depicted to be flat; however, the surface is formed to have a fine irregularity structure in order to confine solar light effectively into the semiconductor substrate 1.

The reflection-preventive film 2 is formed of an insulating material such as silicon nitride (SiNₓ) and suppresses the reflection of solar light shown by an arrow A to the light-receiving surface, so as to guide solar light quickly and efficiently to the semiconductor substrate 1. The material that constitutes this reflection-preventive film 2 is not limited to silicon nitride described above, so that other insulating materials, for example, silicon oxide or titanium oxide, may be used, and also two or more insulating materials may be used in combination. Also, any one of single-crystal Si and polycrystal Si may be used as long as it is a crystal Si type material.

The light-receiving surface electrode 3 is formed on the semiconductor substrate 1 so as to penetrate through the reflection-preventive film 2. This light-receiving surface electrode 3 is formed by using screen printing or the like, applying an electroconductive paste of the present invention described later onto the semiconductor substrate 1 so as to prepare an electroconductive film, and firing the resultant. In other words, in the firing step of the forming light-receiving surface electrode 3, the reflection-preventive film 2 under the electroconductive film is decomposed and removed to give a fire-through, and this allows that the light-receiving surface electrode 3 is formed on the semiconductor substrate 1 in a mode of penetrating through the reflection-preventive film 2.

Specifically, as shown in FIG. 2, the light-receiving surface electrode 3 is formed in such a manner that numerous finger electrodes 5a, 5b, . . . 5n are disposed in parallel in a comb-teeth shape, and a bus bar electrode 6 is disposed to intersect the finger electrodes 5a, 5b, . . . 5n, whereby the finger electrodes 5a, 5b, . . . 5n are electrically connected to the bus bar electrode 6. Further, the reflection-preventive film 2 is formed in a remaining region other than the part where the light-receiving surface electrode 3 is disposed. In this manner, the electric power generated in the semiconductor substrate 1 is collected by the finger electrode 5n and extracted to the outside by the bus bar electrode 6.

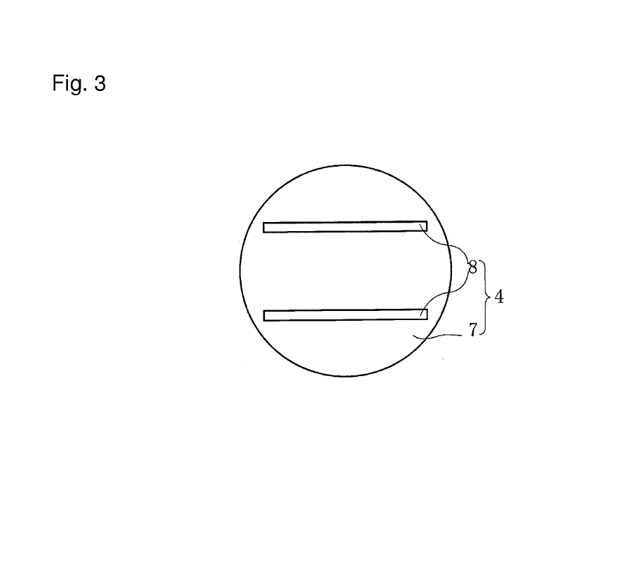

Referring to FIG. 3, the back surface electrode 4 specifically includes a collecting electrode 7 made of Al or the like formed on the back surface of the p-type semiconductor layer 1b and an extraction electrode 8 made of Ag or the like formed on the back surface of the collecting electrode 7 and electrically connected to the collecting electrode 7. Further, the electric power generated in the semiconductor substrate 1 is collected to the collecting electrode 7, and the electric power is extracted by the extraction electrode 8.

Next, the electroconductive paste of the present invention for forming the light-receiving surface electrode 3 will be described in detail.

The electroconductive paste of the present invention contains an electroconductive powder, a glass frit, a binder resin, and a solvent.

Further, the solvent includes a mixed solvent containing at least one first solvent A that contains at least one of a carboxylate group and a hydroxyl group and at least one second solvent B that does not contain the carboxylate and the hydroxyl group and has a hydrogen-bond term among the Hansen solubility parameters of 7 (J/cm³)^{1/2} or less.

In other words, as the solvent contained in the electroconductive paste, typically, a polar solvent containing a carboxylate group or a hydroxyl group, which are polar groups, is used in consideration of the solubility to the binder resin.

However, as described above, the inorganic component such as an electroconductive powder or a glass frit wetted with the organic solvent adheres onto the mask or mesh of the pattern and further adheres onto the semiconductor substrate 1 via the reflection-preventive film 2 by a Coulomb force or a hydrogen bond. As a result of this, the fluidity of the inorganic component to the pattern or the semiconductor substrate 1 decreases, whereby plate clogging is generated and the plate releasing property is deteriorated to invite decrease in the printing property. Also, the packing property of the inorganic component along the fine irregularity structure of the semiconductor substrate 1 decreases, thereby raising a fear that a desired fire-through property cannot be obtained.

Therefore, in the present embodiment, in addition to the first solvent A having a polar group, the second solvent B having a non-polar group is mixed to such a degree that the binder resin does not generate poor dissolution, and the binder resin is dissolved into the mixed solvent obtained by mixing the two solvents.

Specifically, as the second solvent B, a solvent having a hydrogen-bond term δh among the Hansen solubility parameters of 7 (J/cm³)^{1/2} or less is used.

The Hansen solubility parameters are such that the solubility parameter δ introduced by Hildebrand (Hildebrand) in a regular solution theory is divided into three components, that is, a dispersion term δd, a polarity term δp, and a hydrogen-bond term δh, and represented in a three-dimensional space.

The solubility parameter δ introduced by Hildebrand is defined as a square root of the aggregation energy density. However, the solubility parameter δ of Hildebrand can be applied only to non-polar solvents. Therefore, Hansen (Hansen) has enlarged the concept of solubility parameter δ and divided the solubility parameter δ into three components, that is, a dispersion term δd, a polarity term δp, and a hydrogen-bond term δh, as shown in numerical formula (1), to represent them as vectors in a three-dimensional space, and has found out that, by this, the functions of a polar solution and a hydrogen bond can be more definitely described with respect to the solubility of a solvent and a solute.

δ²=δd²+δp²+δh² (1)

Here, the dispersion term δd is a contributing term by non-polar interaction; the polarity term δp is a contributing term by a dipole moment; and the hydrogen-bond term δh is a contributing term by a hydrogen bond force. All of the three contributing terms are values intrinsic to the substance and are described, for example, in Non-patent Document 1.
Non-patent Document 1: “Hansen Solubility Parameters: A User's Handbook”, HSPiP 3rd Edition ver.3.0.20

Here, as the hydrogen-bond term δh of the Hansen solubility parameters, a value in the above-mentioned database can be used; however, when there is no description in the database, the hydrogen-bond term δh of the Hansen solubility parameters can be calculated by an estimation method using the neural network method referred to as the Y-MB method.

In the present embodiment, the hydrogen bond gives a large influence on the solubility of the binder resin in the solvent, the paste rheology, and the close adhesion property between the pattern and the mask, so that the first solvent A and the second solvent B are selected by paying attention to the hydrogen-bond term δh of the Hansen solubility parameters.

A solvent whose hydrogen-bond term δh is close to the hydrogen-bond term δh of a binder resin dissolves the binder resin easily, whereas a solvent whose hydrogen-bond term δh is largely different in value from the hydrogen-bond term δh of a binder resin hardly dissolves the binder resin. In the present embodiment, a solvent having a hydrogen-bond term δh of 8 (J/cm³)^{1/2} or more and containing at least one of a carboxylate group (—COO—) and a hydroxyl group (—OH), which give a good solubility to the binder resin, is used as the first solvent A; a solvent containing neither a carboxylate group nor a hydroxyl group and having a hydrogen-bond term δh of 7 (J/cm³)^{1/2} or less to make the binder resin hardly soluble is used as the second solvent B; and a mixed solvent obtained by mixing the first solvent A and the second solvent B is used as the solvent. This allows the solubility of the binder resin in the solvent and the fluidity to the semiconductor substrate to be compatible with each other, thereby improving the printing property and improving the fire-through property.

In other words, the mixed solvent obtained by mixing the first solvent A and the second solvent B described above decreases in polarity to such a degree that the binder resin does not undergo poor dissolution. By this, the close adhesion property to the mask of the pattern decreases to a suitable extent. Also, since the fluidity to the pattern is enhanced without deteriorating the dissolution property of the binder resin in the solvent, the amount of ejection to the reflection-preventive film 2 increases, and the plate clogging is less liable to occur, thereby improving the plate releasing property. As a result of this, even when continuous printing is carried out, disconnection of the electrode pattern can be suppressed, whereby the continuous printing property is improved.

Also, since the fluidity of the inorganic component to the semiconductor substrate 1 is enhanced, the packing property of the inorganic component to the semiconductor substrate surface is improved. As a result of this, the fire-through property is improved, and the conversion efficiency can be improved.

Further, such a first solvent A is not particularly limited as long as the first solvent A contains at least one of a carboxylate group and a hydroxyl group, so that, for example, one or more selected from texanol ((CH₃)₂CHCHOHC(CH₃)₂CH₂COOCH(CH₃)₂); hydrogen-bond term δh=9.8), dimethyl adipate (H₃COOC(CH₂)₄COOCH₃; hydrogen-bond term δh=9.2), BCA (H₉C₄O(CH₂CH₂O)₂COOCH₃; hydrogen-bond term δh=8.2), and BC(H₉C₄O(CH₂)₂OCH₂CH₂OH; hydrogen-bond term δh=10.6) can be used, for example.

Also, the second solvent B is not particularly limited as long as the second solvent B contains neither a carboxylate group nor a hydroxyl group and has a hydrogen-bond term δh among the Hansen solubility parameters of 7 (J/cm³)^{1/2} or less, so that, for example, DEGBME (H₉C₄O(CH₂CH₂O)₂CH₃; hydrogen-bond term δh=6.1),

TEGBME (H₉C₄O(CH₂CH₂O)₃CH₃; hydrogen-bond term δh=6.6), DEGDEE (H₅C₂O(CH₂CH₂O)₂C₂H₅; hydrogen-bond term δh=6.4), propylene carbonate (C₄H₆O₃; hydrogen-bond term δh=4.2), and n-tetradecane (C₁₄H₃₀; hydrogen-bond term δh=0) can be used.

In particular, among these second solvents B, it is preferable to use a solvent in which the molar ratio of the oxygen moiety to the carbon moiety within a molecular structure is 0.3 or more.

In other words, since the firing process is carried out in an extremely short period of time (for example, 1 to 3 minutes), there is a fear that there may be a solvent that remains without being dried. For this reason, when a solvent in which the molar ratio of the oxygen moiety to the carbon moiety within a molecular structure is less than 0.3 is used, there is a fear that the oxygen concentration around the light-receiving surface electrode may decrease when the solvent is fired, and the fire-through property may decrease due to the soot generated by firing, thereby inviting decrease in the conversion efficiency.

Due to such reasons, it is preferable that a solvent in which the molar ratio of the oxygen moiety to the carbon moiety within a molecular structure is 0.3 or more is used as the second solvent B.

Further, as such a second solvent B, the other three solvents excluding n-tetradecane (O/C=0) among the second solvents B described above, that is, DEGBME (0/C=0.33), TEGBME (O/C=0.36), DEGDEE (O/C=0.375), and propylene carbonate (O/C=0.75) are suitable.

Here, the mixing ratio of the first solvent A and the second solvent B is not particularly limited and can be suitably determined in accordance with the numerical value of the hydrogen-bond term δh of each of the first solvent A and the second solvent B. For example, in the case of the solvents listed above, the fluidity to the pattern or the semiconductor substrate 1 can be ensured without deteriorating the solubility of the binder resin by mixing in such a manner that the ratio A/B of the first solvent A to the second solvent B is within a range from 7/1 to 1/3. By this, an electroconductive paste having a good printing property and being capable of obtaining a solar cell having good cell characteristics can be realized.

Also, the binder resin is not particularly limited as long as impartation of fluidity at the time of filling with a paste by squeezing at the time of printing or spreading (dripping) or the like of the paste after plate releasing can be suppressed, so that an ethyl cellulose resin, a cellulose acetate butyrate resin, a nitrocellulose resin, a urethane resin, an aliphatic acid amide, a hydrogenated castor oil, a rosin resin, a ketone resin, or a combination of these can be used.

The glass frit is also not particularly limited, so that, for example, a Si—B—Bi-M type glass frit (M is an alkali earth metal) can be used. However, a Pb type glass frit imposes a large load on the environment as compared with a non-Pb type glass frit, though the fire-through property is good, so that use thereof is not preferable. In the present embodiment, the printing property can be improved and the fire-through property can be improved even without the use of a Pb type glass frit, so that it is preferable to use a non-Pb type glass frit.

Further, the present invention is particularly effective in the case in which the electroconductive powder has hydrophilicity. In other words, when only a solvent having a polar group is used in the case in which the electroconductive powder has hydrophilicity, the electroconductive powder adheres to the mask or mesh of the pattern and further to the semiconductor substrate 1 by a Coulomb force or hydrogen bond, thereby raising a fear that particularly the packing property of the inorganic component to the semiconductor substrate 1 may decrease to invite decrease in the fire-through property.

In contrast, when a mixed solvent obtained by mixing the first solvent A and the second solvent B is used in the case in which the electroconductive powder has hydrophilicity, the close adhesion property to the mask decreases, and the fluidity on the semiconductor substrate is enhanced to improve the packing property, so that the fire-through property can be improved.

Here, the electroconductive powder is not particularly limited as long as it is a metal powder having a good electric conductivity. However, an Ag powder that can maintain a good electric conductivity without being oxidized even when the firing process is carried out in an ambient atmosphere is preferably used. Here, the shape of this electroconductive powder is not particularly limited, and the electroconductive powder may have a spherical shape, a flattened shape, or an amorphous shape, or may be a mixed powder of these.

Also, the average particle size of the electroconductive powder is not particularly limited; however, the average particle size is preferably from 1.0 μm to 5.0 μm as converted in terms of spherical powder in view of ensuring a desired contact point between the electroconductive powder and the semiconductor substrate 1.

Further, it is also preferable that ZnO is contained in the electroconductive paste. In other words, in firing the electroconductive paste, ZnO promotes decomposition and removal of the reflection-preventive film formed in advance on the surface of the semiconductor substrate 1 to enable a smooth fire-through and to lower the contact resistance between the light-receiving surface electrode 3 and the semiconductor substrate 1. Here, in this case, it seems that the function of decomposing the reflection-preventive film is generated at the site where the electroconductive powder and ZnO are in contact with each other.

This electroconductive paste can be easily produced by weighing, mixing, and stirring an electroconductive powder, a glass frit, a binder resin, and first and second solvents so as to attain a predetermined mixing ratio, and dispersing and kneading the mixture by using a triple roll mill or the like.

In this manner, in the present embodiment, the electroconductive paste contains an electroconductive powder such as Ag, a glass frit preferably not substantially containing Pb, a binder resin, and a solvent, wherein the solvent contains at least one first solvent A that contains at least one of a carboxylate group and a hydroxyl group and at least one second solvent B that does not contain the carboxylate and the hydroxyl group and has a hydrogen-bond term among the Hansen solubility parameters of 7 (J/cm³)^{1/2} or less. Therefore, in the electroconductive paste, the close adhesion property to the mask or mesh of the pattern decreases to a suitable extent at the time of printing. Further, the fluidity to the pattern is enhanced without deteriorating the dissolution property of the binder resin, and the amount of ejection increases, so that the plate clogging is less liable to occur, and the plate releasing property is improved. Furthermore, even when continuous printing is carried out, disconnection of the electroconductive film can be suppressed, and the printing property is improved. Also, since the fluidity of the inorganic component to the semiconductor substrate is enhanced, the packing property of the inorganic component to the semiconductor substrate surface is improved. As a result of this, the fire-through property is improved, and the conversion efficiency can be improved.

Also, by allowing the second solvent B to have at least an oxygen moiety and a carbon moiety within a molecular structure and setting a molar ratio of the oxygen moiety to the carbon moiety to be 0.3 or more, a further improvement of the fire-through property can be achieved without deteriorating the printing property.

Further, the printing property and the fire-through property can be improved particularly effectively when the electroconductive powder is hydrophilic.

In this manner, according to the electroconductive paste, the dissolution property to the binder resin and the fluidity to the pattern or the semiconductor substrate can be made compatible with each other.

Furthermore, by using the electroconductive paste in a light-receiving surface electrode, the solar cell according to the present invention has an advantage of having a good printing property and a good fire-through property, so that a solar cell being excellent in mass productivity, having a good conversion efficiency, and being excellent in cell characteristics can be obtained.

Here, the present invention is not limited to the above-described embodiments, and it is preferable that, for example, one plasticizer such as di-2-ethylhexyl phthalate or dibutyl phthalate or a combination of these is added to the electroconductive paste if necessary. Also, a thixotropic agent, a thickening agent, a dispersing agent, or the like may be added, and a rheology adjusting agent such as aliphatic acid amide or aliphatic acid may be added if necessary.

Also, in the present invention, it is sufficient that the electroconductive paste contains at least one of each of the first solvent A and the second solvent, so that the electroconductive paste may contain two or more of each.

Next, Examples of the present invention will be specifically described.

### Example 1

### Preparation of Sample

As an electroconductive powder, a spherical Ag powder having an average particle size of 1.6 μm was prepared. Then, this Ag powder was mixed with a surface treatment agent containing an amide group, and the mixture was washed and dried, thereby to perform a hydrophilizing treatment on the Ag powder.

Also, ZnO having a specific surface area of 10 m²/g, an ethylcellulose resin serving as a binder resin, a B—Si—Bi—Ba type glass frit, and texanol, dimethyl adipate, BCA, and BC as a first solvent A were each prepared, and further, propylene carbonate, DEGDEE, DEGBME, TEGBME, and n-tetradecane were prepared as a second solvent B.

Then, these were weighed so as to attain a weight composition shown in Table 1 and mixed with a planetary mixer, followed by kneading with a triple roll mill to prepare an electroconductive paste of each of Sample Numbers 1 to 11.

TABLE 1

| | Paste composition (wt %) | | | | | | | | | | | | | |
|---|---|---|---|---|---|---|---|---|---|---|---|---|---|---|
| | | | | | First solvent A | | | | Second solvent B | | | | | Mixing |
| | | | | Ethyl | | Dimethyl | | | Propylene | | | | Tetra- | ratio of |
| Sam- | | | | cellu- | Texanol | adipate | BCA | BC | carbonate | DEGDEE | DEGBME | TEGBME | decane | solvents |
| ple | | Glass | | lose | δh = | δh = | δh = | δh = | δh = 4.2 | δh = 6.4 | δh = 6.1 | δh = 6.6 | δh = 0 | A/B |
| No. | Ag | frit | ZnO | resin | 9.8 | 9.2 | 8.2 | 10.6 | O/C = 0.75 | O/C = 0.375 | O/C = 0.33 | O/C = 0.36 | O/C = 0 | (—) |
| 1 | 83.0 | 2.0 | 5.0 | 2.0 | 6.0 | — | — | — | 2.0 | — | — | — | — | 3/1 |
| 2 | 83.0 | 2.0 | 5.0 | 2.0 | 6.0 | — | — | — | — | 2.0 | — | — | — | 3/1 |
| 3 | 83.0 | 2.0 | 5.0 | 2.0 | 6.0 | — | — | — | — | — | 2.0 | — | — | 3/1 |
| 4 | 83.0 | 2.0 | 5.0 | 2.0 | 6.0 | — | — | — | — | — | — | 2.0 | — | 3/1 |
| 5** | 83.0 | 2.0 | 5.0 | 2.0 | 6.0 | — | — | — | — | — | — | — | 2.0 | 3/1 |
| 6* | 83.0 | 2.0 | 5.0 | 2.0 | 8.0 | — | — | — | — | — | — | — | — | 10/0 |
| 7* | 83.0 | 2.0 | 5.0 | 2.0 | — | 8.0 | — | — | — | — | — | — | — | 10/0 |
| 8* | 83.0 | 2.0 | 5.0 | 2.0 | 6.0 | 2.0 | — | — | — | — | — | — | — | 10/0 |
| 9* | 83.0 | 2.0 | 5.0 | 2.0 | 6.0 | — | 2.0 | — | — | — | — | — | — | 10/0 |
| 10* | 83.0 | 2.0 | 5.0 | 2.0 | 6.0 | — | — | 2.0 | — | — | — | — | — | 10/0 |
| 11* | 83.0 | 2.0 | 5.0 | 2.0 | — | — | — | — | 8.0 | — | — | — | — | 0/10 |

*out of the range of the present invention (claim 1)
**out of the range of the present invention (claim 3)

As will be clear from this Table 1, in Sample Numbers 1 to 5, the first solvent A and the second solvent B are blended so that the mixing ratio A/B is 3/1. Also, Sample Numbers 6 to 10 are samples of Comparative Examples in which only the first solvent A is used as the solvent, and Sample Number 11 is a sample of Comparative Example in which only the second solvent B is used as the solvent.

[Evaluation of Samples]

A solar cell was prepared to evaluate the printing property of the electroconductive paste and the cell characteristics of the solar cell.

In other words, a reflection-preventive film having a film thickness of 0.1 μm was formed by the plasma enhanced chemical vapor deposition method (PECVD) on the whole area of the surface of a single-crystal Si-based semiconductor substrate having a longitudinal side of 50 mm, a lateral side of 50 mm, and a thickness of 0.2 mm. Here, this Si-based semiconductor substrate is formed in such a manner that P is diffused into a part of a p-type Si-based semiconductor layer, whereby an n-type Si-based semiconductor layer is formed on the upper surface of the p-type Si-based semiconductor layer.

Subsequently, an Al paste containing Al and an Ag paste containing Ag were suitably applied onto the back surface of the Si-based semiconductor substrate, followed by drying to form an electroconductive film for a back surface electrode.

Next, with use of the electroconductive paste, screen printing was carried out at a speed with a squeegee speed of 200 mm/s, so as to prepare an electroconductive film for a light-receiving surface electrode having a predetermined pattern so that the electrode width of the finger electrodes was 80 μm.

Subsequently, the continuous printing property and the ejection property of the electroconductive paste were confirmed.

Here, with respect to the continuous printing property, the case in which the electroconductive film was disconnected at the time of screen printing with ten continuous sheets or below was evaluated as a failure (x), and the case in which the electroconductive film was not disconnected at the time of screen printing exceeding ten continuous sheets was evaluated as a pass (o). Here, the presence or absence of the disconnection of the electroconductive film was determined by visual inspection.

Also, with respect to the ejection property, screen printing was carried out by adjusting a screen plate so that the film thickness of the electroconductive film was 30 μm, and the case in which the film thickness of the electroconductive film was 70% or less of a designed value, namely, 21 μm or less, was evaluated as a failure (x), whereas the case in which the film thickness of the electroconductive film exceeded 21 μm was evaluated as a pass (o).

Next, each sample was put into an oven set at a temperature of 150° C., so as to dry the electroconductive film.

Thereafter, with use of a belt-type near infrared furnace (CDF7210 manufactured by Despatch Industries G.K.), the sample was fired at a peak temperature of 790° C. in an ambient atmosphere by adjusting the transportation speed so that the sample passed between the entrance and the exit in about one minute, so as to prepare a solar cell of each of Sample Numbers 1 to 11, in which the electroconductive paste was sintered to form an electrode.

With respect to each of the samples of Sample Numbers 1 to 11, a current-voltage characteristic curve was measured under conditions with a temperature of 25° C. and an AM (air mass)-1.5 by using a solar simulator (SS-50XIL manufactured by EKO Instruments Co., Ltd.), and a fill factor FF represented by numerical formula (2) was determined from this current-voltage characteristic curve.

FF=Pₘₐₓ/(V_{oc}×I_{sc}) (2)

Here, Pₘₐₓ is the maximum output of the sample; V_{oc} is an open circuit voltage; and I_{sc} is a short-circuit current.

Also, the conversion efficiency η was determined on the basis of numerical formula (3) from the maximum output Pₘₐₓ, an area A of the light-receiving surface electrode, and radiation illuminance E.

=Pₘₐₓ/(A×E) (3)

Table 2 shows the printing property (continuous printing property, ejection property) and the cell characteristics (fill factor FF, conversion efficiency η) of Sample Numbers 1 to 11.

TABLE 2

| | Printing property | | Cell characteristics | |
|---|---|---|---|---|
| | Continuous | | | Conversion |
| Sample | printing | Ejection | Fill factor FF | efficiency η |
| No. | property | property | (—) | (%) |
| 1 | ◯ | ◯ | 0.769 | 16.49 |
| 2 | ◯ | ◯ | 0.765 | 16.27 |
| 3 | ◯ | ◯ | 0.766 | 16.49 |
| 4 | ◯ | ◯ | 0.766 | 16.41 |
| 5** | ◯ | ◯ | 0.749 | 16.08 |
| 6* | X | X | 0.745 | 15.78 |
| 7* | X | ◯ | 0.701 | 14.53 |
| 8* | X | ◯ | 0.657 | 14.00 |
| 9* | X | ◯ | 0.721 | 15.50 |
| 10* | X | X | 0.715 | 15.20 |
| 11* | — | — | — | — |

*out of the range of the present invention (claim 1)
**out of the range of the present invention (claim 3)

With respect to Sample Number 6, disconnection occurred at the time of continuous printing because only texanol containing a carboxylate group and a hydroxyl group was used as the solvent. Also, the film thickness of the electroconductive film was small, and the ejection property decreased. For this reason, it has been found out that the fill factor FF was as low as 0.745, and the conversion efficiency η was as low as 15.78%.

With respect to Sample Number 7, though the ejection property was good, disconnection occurred at the time of continuous printing because only dimethyl adipate containing a carboxylate group was used. For this reason, the fill factor FF was as low as 0.701, and the conversion efficiency η was as low as 14.53%.

With respect to each of Sample Numbers 8 and 9, though the ejection property was good, disconnection occurred at the time of continuous printing in the same manner as in Sample Number 7, because only the first solvent A containing a carboxylate group and a hydroxyl group was used though two solvents were mixed. Also, the fill factor FF was as low as 0.657 and 0.721, respectively, and the conversion efficiency η was as low as 14.00% and 15.50%, respectively.

With respect to Sample Number 10, the ejection property decreased because only the first solvent A containing a carboxylate group and a hydroxyl group was used. For this reason, disconnection occurred at the time of continuous printing, and the film thickness of the electroconductive film was small. Also, the fill factor FF was as low as 0.715, and the conversion efficiency η was as low as 15.20%.

With respect to Sample Number 11, the binder resin was not dissolved in the solvent and a paste could not be formed, because only propylene carbonate serving as the second solvent B was used.

In contrast, with respect to each of Sample Numbers 1 to 5, the continuous printing property and the ejection property were good because the first solvent A and the second solvent B were mixed. For this reason, it has been found out that the fill factor FF was improved to be 0.749 to 0.769, and the conversion efficiency η was improved to be 16.08% to 16.49%.

In particular, with respect to each of Sample Numbers 1 to 4 in which the molar ratio of the oxygen moiety to the carbon moiety in a molecular structure was 0.3 or more, it has been found out that both the fill factor FF and the conversion efficiency η were improved as compared with the Sample Number 5 in which the molar ratio was less than 0.3, whereby the cell characteristics were improved.

### Example 2

By using texanol as the first solvent A and using propylene carbonate as the second solvent B, electroconductive pastes of Sample Numbers 21 to 24 having different mixing ratios A/B were prepared by the same method and procedure as those of [Example 1]. Further, by using the electroconductive pastes, solar cells of Sample Numbers 21 to 24 were prepared.

Subsequently, with respect to each of the samples of Sample Numbers 21 to 24, the printing property (continuous printing property, ejection property) and the cell characteristics (fill factor FF, conversion efficiency η) were evaluated by the same method and procedure as those of Example 1.

Table 3 shows the printing property (continuous printing property, ejection property) and the cell characteristics (fill factor FF, conversion efficiency η) of Sample Numbers 21 to 24.

TABLE 3

| | Paste composition (wt %) | | | | | | Mixing | | | | |
|---|---|---|---|---|---|---|---|---|---|---|---|
| | | | | | Texanol | Propylene | ratio of | Printing property | | Cell characteristics | |
| | | | | Ethyl | (first | carbonate | solvents | Continuous | | | Conversion |
| Sample | | Glass | | cellulose | solvent A) | (second solvent B) | A/B | printing | Ejection | Fill factor | efficiency η |
| No. | Ag | frit | ZnO | resin | δh = 9.8 | δh = 4.2 | (—) | property | property | FF (—) | (%) |
| 21 | 83.0 | 2.0 | 5.0 | 2.0 | 7.0 | 1.0 | 7/1 | ◯ | ◯ | 0.768 | 16.35 |
| 22 | 83.0 | 2.0 | 5.0 | 2.0 | 6.0 | 2.0 | 3/1 | ◯ | ◯ | 0.769 | 16.49 |
| 23 | 83.0 | 2.0 | 5.0 | 2.0 | 4.0 | 4.0 | 5/5 | ◯ | ◯ | 0.760 | 16.40 |
| 24 | 83.0 | 2.0 | 5.0 | 2.0 | 2.0 | 6.0 | 1/3 | ◯ | ◯ | 0.745 | 16.28 |

As will be clear from Sample Numbers 21 to 24, it has been confirmed that the printing property and the ejection property were good, and a solar cell having a good fill factor FF and a good conversion efficiency η was obtained in the same manner as in Example 1 even when the mixing ratio A/B of texanol and propylene carbonate was changed within a range from 7/1 to 1/3.

### Example 3

As an electroconductive powder, a spherical Ag powder having an average particle size of 1.6 μm was prepared. Then, this Ag powder was mixed with stearic acid, and the mixture was washed and dried, thereby to perform a hydrophobizing treatment on the Ag powder.

Subsequently, each of the samples of Sample Numbers 31 to 35 was prepared by the same method and procedure as those of Example 1 while setting the mixing ratio of the solvent species and the solvent to be the same as in Sample Numbers 1 to 3, 5, and 8.

Next, with respect to each of the samples of Sample Numbers 31 to 35, the printing property (continuous printing property, ejection property) and the cell characteristics (fill factor FF, conversion efficiency η) were evaluated by the same method and procedure as those of Example 1.

Table 4 shows the printing property (continuous printing property, ejection property) and the cell characteristics (fill factor FF, conversion efficiency η) of Sample Numbers 31 to 35.

Here, in this Table 4, the printing property and the cell characteristics of each of Sample Numbers 1 to 3, 5, and 8 are shown again for the sake of comparison.

TABLE 4

| | | Printing property | | Cell characteristics | | |
|---|---|---|---|---|---|---|
| | | Contin- | | Fill | | |
| Sam- | | uous | | factor | Conversion | |
| ple | | printing | Ejection | FF | efficiency | |
| No. | Ag | property | property | (—) | η (%) | Notes |
| 1 | Hydro- | ◯ | ◯ | 0.769 | 16.49 | |
| 2 | phil- | ◯ | ◯ | 0.765 | 16.27 | |
| 3 | icity | ◯ | ◯ | 0.766 | 16.49 | |
| 5 | | ◯ | ◯ | 0.749 | 16.08 | |
| 8* | | X | ◯ | 0.657 | 14.00 | |
| 31 | Hydro- | ◯ | ◯ | 0.755 | 16.32 | The solvents |
| | pho- | | | | | are the same |
| | bicity | | | | | as in Sample |
| | | | | | | No. 1 |
| 32 | | ◯ | ◯ | 0.753 | 16.40 | The solvents |
| | | | | | | are the same |
| | | | | | | as in Sample |
| | | | | | | No. 2 |
| 33 | | ◯ | ◯ | 0.750 | 16.25 | The solvents |
| | | | | | | are the same |
| | | | | | | as in Sample |
| | | | | | | No. 3 |
| 34 | | ◯ | ◯ | 0.737 | 15.95 | The solvents |
| | | | | | | are the same |
| | | | | | | as in Sample |
| | | | | | | No. 5 |
| 35* | | X | ◯ | 0.732 | 15.91 | The solvents |
| | | | | | | are the same |
| | | | | | | as in Sample |
| | | | | | | No. 8 |

*out of the range of the present invention (claim 1)

As will be clear from the comparison between Sample Numbers 31 to 34 and Sample Number 35, only a little improvement in the cell characteristics is seen when the Ag powder is hydrophobic.

In contrast, as will be clear from the comparison between Sample Numbers 1 to 3 and 5 and Sample Number 8, a remarkable improvement in the cell characteristics is seen when the Ag powder is hydrophilic, whereby it has been found out that the present invention is more effective when the Ag powder is hydrophilic.

A non-lead-type electroconductive paste having a good printing property and ejection property and having good cell characteristics can be realized, whereby a solar cell having a high conversion efficiency can be obtained stably with a good efficiency.

### DESCRIPTION OF REFERENCE SYMBOLS

1 semiconductor substrate
2 reflection-preventive film
3 light-receiving surface electrode (electrode)
4 back surface electrode

1. An electroconductive paste comprising:
an electroconductive powder;
a glass frit;
a binder resin;
a first solvent that contains at least one of a carboxylate group and a hydroxyl group; and
a second solvent that does not contain the carboxylate and the hydroxyl group and has a hydrogen-bond term among Hansen solubility parameters of 7 (J/cm³)^{1/2} or less.

2. The electroconductive paste according to claim 1, wherein the second solvent contains at least one solvent selected from the group consisting of diethylene glycol butyl methyl ether, triethylene glycol butyl methyl ether, diethylene glycol diethyl ether, propylene carbonate, and n-tetradecane.

3. The electroconductive paste according to claim 1, wherein the second solvent has at least an oxygen moiety and a carbon moiety within a molecular structure, and a molar ratio of the oxygen moiety to the carbon moiety is 0.3 or more.

4. The electroconductive paste according to claim 1, wherein the second solvent contains at least one solvent selected from the group consisting of diethylene glycol butyl methyl ether, triethylene glycol butyl methyl ether, diethylene glycol diethyl ether, and propylene carbonate.

5. The electroconductive paste according to claim 1, wherein the electroconductive powder is hydrophilic.

6. The electroconductive paste according to claim 1, wherein the electroconductive powder is an Ag powder.

7. The electroconductive paste according to claim 1, wherein the glass frit does not contain lead.

8. The electroconductive paste according to claim 1, wherein the first solvent has a hydrogen-bond term among the Hansen solubility parameters of 8 (J/cm³)^{1/2} or more. (from new paragraph [0064])

9. The electroconductive paste according to claim 8, wherein the first solvent contains at least one solvent selected from the group consisting of texanol, dimethyl adipate, butylcarbitol acetate, and butylcarbitol. (from new paragraph [0067])

10. The electroconductive paste according to claim 1, wherein a ratio of the first solvent to the second solvent is within a range from 7/1 to 1/3. (from new paragraph [0074])

11. The electroconductive paste according to claim 1, wherein the binder resin is one or more resins selected from the group consisting of ethyl cellulose resins, cellulose acetate butyrate resins, nitrocellulose resins, urethane resins, aliphatic acid amides, hydrogenated castor oils, rosin resins, and ketone resins. (from new paragraph [0075]

12. The electroconductive paste according to claim 1, wherein the electroconductive powder has an average particle size from 1.0 μm to 5.0 μm. (from new paragraph [0080])

13. The electroconductive paste according to claim 1, further comprising ZnO. (from new paragraph [0081]

14. A solar cell comprising:
a semiconductor substrate;
a reflection-preventive film adjacent a first surface of the semiconductor substrate; and
an electrode penetrating through the reflection-preventive film,
wherein the electrode is formed by sintering the electroconductive paste according to claim 1.

15. The solar cell according to claim 14, wherein the semiconductor substrate comprises a p-type semiconductor layer and an n-type semiconductor layer, the n-type semiconductor layer being the first surface of the semiconductor substrate. (from new paragraph [0044])

16. The solar cell according to claim 14, wherein the electrode comprises a plurality of finger electrodes electrically connected to a bus bar electrode. (from new paragraph [0048])

17. The solar cell according to claim 16, wherein the plurality of finger electrodes are disposed in parallel in a comb-teeth shape. (from new paragraph [0048])
